(19) United States
(12) Patent Application Publication
(10) Pub. No.: US 2012/0008412 A1
(43) Pub. Date: Jan. 12, 2012

(54) NONVOLATILE MEMORY DEVICE AND METHOD OF ERASING THE SAME

(75) Inventor: Young Soo PARK, Seoul (KR)

(73) Assignee: HYNIX SEMICONDUCTOR INC., Icheon-si (KR)

(21) Appl. No.: 13/177,002

(22) Filed: Jul. 6, 2011

(30) Foreign Application Priority Data
Jul. 9, 2010 (KR) 10-2010-0066526

(51) Int. Cl. G11C 16/06

(52) U.S. Cl. 365/185.22

(57) ABSTRACT

A method of erasing a nonvolatile memory device includes the steps of supplying an erase voltage to the P well of a semiconductor substrate having a memory cell block disposed therein; performing a first erase verification operation for verifying the erase state of memory cells coupled to the even bit lines of the memory cell block; making a determination of success or failure for the first erase verification operation; and if, as a result of the determination for the first erase verification operation, all the memory cells coupled to the even bit lines are determined to be erased, performing a second erase verification operation for verifying the erase state of memory cells coupled to odd bit lines of the memory cell block.

### CROSS-REFERENCE TO RELATED APPLICATION

Priority is claimed to Korean patent application number 10-2010-0066526 filed on Jul. 9, 2010, the entire disclosure of which is incorporated by reference herein.

### BACKGROUND

Exemplary embodiments relate generally to a memory device and, more particularly, to novel and useful erasing operations in a nonvolatile memory device.

A desirable feature sought in the nonvolatile memory devices is the ability to electrically program and erase with no need for a refresh function for rewriting data at specific intervals. To program is to write data to memory cells, and to erase is to erase data written in the memory cells.

For higher degree of integration, a plurality of memory cells in a NAND type flash memory device is coupled in series to form a string (that is, the neighboring memory cells share a drain or a source). Unlike a NOR type flash memory device, the NAND type flash memory device sequentially reads information.

In a NAND type flash memory device, a program operation is performed on a page basis, and an erase operation is performed on a block basis. Accordingly, a program verification operation is performed for one page, and an erase verification operation is performed for one block.

FIG. 1 illustrates waveforms of an erase voltage and a verification voltage in a conventional erase operation of a nonvolatile memory device.

Referring to FIG. 1, each time after a high level erase voltage of is provided to the P well of a memory cell block, a verification operation is performed for the memory cells coupled to the even bit lines of the memory cell array, and another verification operation is performed for the memory cells coupled to the odd bit lines thereof. That is, after one verification voltage is supplied, the verification operation is performed for the memory cells coupled to each of the even bit lines and the odd bit lines. Accordingly, the time taken to perform the erase verification operation in the erase operation is increased.

### BRIEF SUMMARY

Exemplary embodiments relate to a nonvolatile memory device and a method of erasing the same which are capable of improving the speed of an erase operation.

According to an aspect of this disclosure, there is provided a nonvolatile memory device, including a memory cell block configured to include a plurality of bit lines having a plurality of memory cells coupled thereto; a circuit group configured to erase the memory cell block; and a controller configured to control the circuit group, wherein the controller controls the circuit group so that the circuit group performs processes of supplying an erase voltage to the P well of a semiconductor substrate having the memory cell block disposed therein, performing a first erase verification operation for verifying an erase state of memory cells, coupled to the even bit lines of the plurality of bit lines, by supplying a verification voltage to relevant word lines of the memory cell block, if a result of the first erase verification operation is determined to be failure, raising the erase voltage by a step voltage and supplying the raised erase voltage to the P well, performing a second erase verification operation for verifying an erase state of memory cells, coupled to the odd bit lines of the plurality of bit lines, and if a result of the second erase verification operation is determined to be failure, raising the erase voltage by the step voltage, supplying the raised erase voltage to the P well, and performing the processes from the process of performing the first erase verification operation.

According to another aspect of this disclosure, there is provided a nonvolatile memory device, including a memory cell block configured to include a plurality of even and odd bit lines having a plurality of memory cells coupled thereto; a page buffer unit coupled to the plurality of even and odd bit lines and configured to detect the verification data of the plurality of memory cells; and a voltage generator configured to supply a verification voltage to the word lines of the memory cell block and supply an erase voltage to the P well of a semiconductor substrate having the memory cell block disposed therein, wherein after the voltage generator supplies the erase voltage to the P well, the page buffer unit performs an erase verification operation for memory cells coupled to the even bit lines, from among the plurality of memory cells, and if a result of the erase verification operation is determined to be success, performs the erase verification operation for memory cells coupled to the odd bit lines, from among the plurality of memory cells.

Yet according to an embodiment of this disclosure, there is provided a method of erasing a nonvolatile memory device, including the steps of supplying an erase voltage to the P well of a semiconductor substrate having a memory cell block disposed therein; performing a first erase verification operation for verifying an erase state of memory cells coupled to the even bit lines of the memory cell block by supplying a verification voltage to relevant word lines of the memory cell block; making a determination of success or failure for the first erase verification operation; and if, as a result of the determination for the first erase verification operation, all the memory cells coupled to the even bit lines are determined to be erased, performing a second erase verification operation for verifying an erase state of memory cells coupled to the odd bit lines of the memory cell block.

Still yet, according to an embodiment of this disclosure, there is provided a method of erasing a nonvolatile memory device, including the steps of supplying an erase voltage to the P well of a semiconductor substrate having a memory cell block disposed therein; performing an even verification operation for verifying an erase state of memory cells coupled to even bit lines of the memory cell block; if a result of the even verification operation is determined to be failure, raising the erase voltage by a step voltage and performing the steps from the step of supplying the erase voltage to the P well by using the raised erase voltage; if the result of the even verification operation is determined to be success, performing an odd verification operation for verifying an erase state of memory cells coupled to odd bit lines of the memory cell block; if a result of the odd verification operation is determined to be failure, raising the erase voltage by the step voltage, supplying the raised erase voltage to the P well, and performing the odd verification operation again; and if the result of the odd verification operation is determined to be success, finishing an erase operation.

Further yet, according to an embodiment of this disclosure, there is provided a method of erasing a nonvolatile memory device, including the steps of supplying an erase voltage to the P well of a semiconductor substrate having a memory cell block disposed therein; performing a first erase verification operation for verifying an erase state of memory cells coupled to the even bit lines of the memory cell block by supplying a verification voltage to relevant word lines of the memory cell block; if a result of the first erase verification operation is determined to be failure, raising the erase voltage by a step voltage and supplying the raised erase voltage to the P well; performing a second erase verification operation for verifying an erase state of memory cells coupled to the odd bit lines of the memory cell block; and if a result of the second erase verification operation is determined to be the failure, raising the erase voltage by the step voltage, supplying the raised erase voltage to the P well, and performing the steps from the step of performing the first erase verification operation.

### BRIEF DESCRIPTION OF THE DRAWINGS

FIG. 1 is a waveform showing an erase voltage and a verification voltage for illustrating a known method of erasing a nonvolatile memory device;

FIG. 2 shows the construction of a nonvolatile memory device according to an embodiment of this disclosure;

FIG. 3 is a flowchart illustrating a method of erasing the nonvolatile memory device according to an embodiment of this disclosure;

FIG. 4 is a waveform showing an erase voltage and a verification voltage for illustrating a method of erasing the nonvolatile memory device according to an embodiment of this disclosure; and

FIG. 5 is a flowchart illustrating an alternative method of erasing the nonvolatile memory device according to an embodiment of this disclosure.

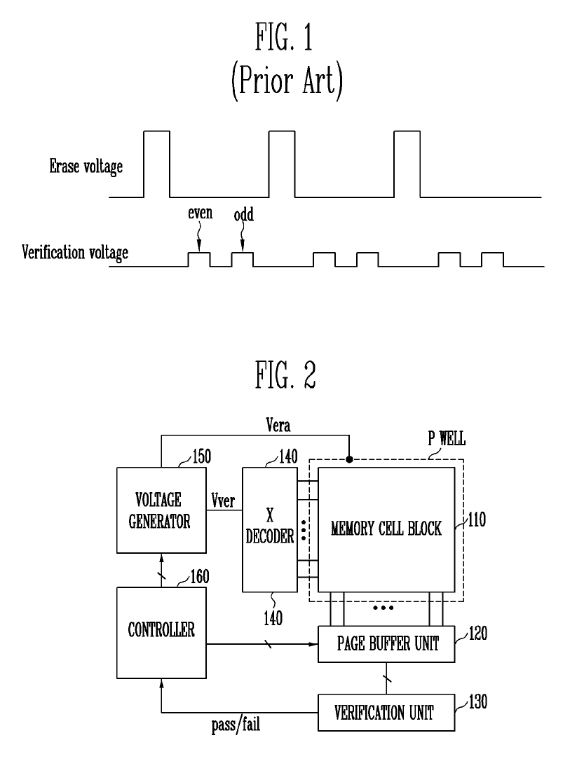

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

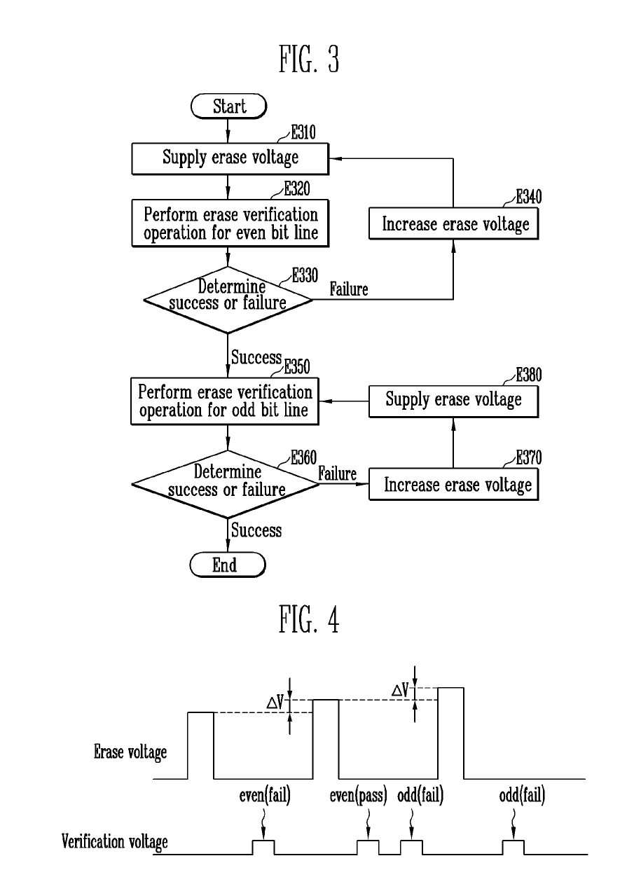

FIG. 2 shows the construction of a nonvolatile memory device according to an embodiment of this disclosure.

Referring to FIG. 2, the nonvolatile memory device includes a memory cell block 110, a page buffer unit 120, a verification unit 130, an X decoder 140, a voltage generator 150, and a controller 160.

The memory cell block 110 includes memory cells configured to store data and coupled to word lines WL and bit lines BL. The page buffer unit 120 includes a plurality of page buffers coupled to the even and odd bit lines of the memory cell array 110. One page buffer may be coupled to the even and odd bit lines or may be coupled to one bit line.

In an erase verification operation of the nonvolatile memory device, the verification unit 130 receives verification data from the page buffer unit 120 and determines the result of an erase operation for memory cells coupled to a bit line based on the received verification data. The X decoder 140 selects a word line WL of the memory cell block 110 and supplies a verification voltage Vver to the word line of the memory cell block 110 in the erase operation.

The voltage generator 150 generates an erase voltage Vera of a high level and verification voltage Vver under the control of the controller 160 during the erase operation. The generated erase voltage Vera is supplied to the P well of a semiconductor substrate having the memory cell block 110 disposed therein, and the generated verification voltage Vver is transmitted to the X decoder 150.

The controller 160 controls the erase operation by controlling the voltage generator 150 and the page buffer unit 120 in response to a success or failure signal generated from the verification unit 130.

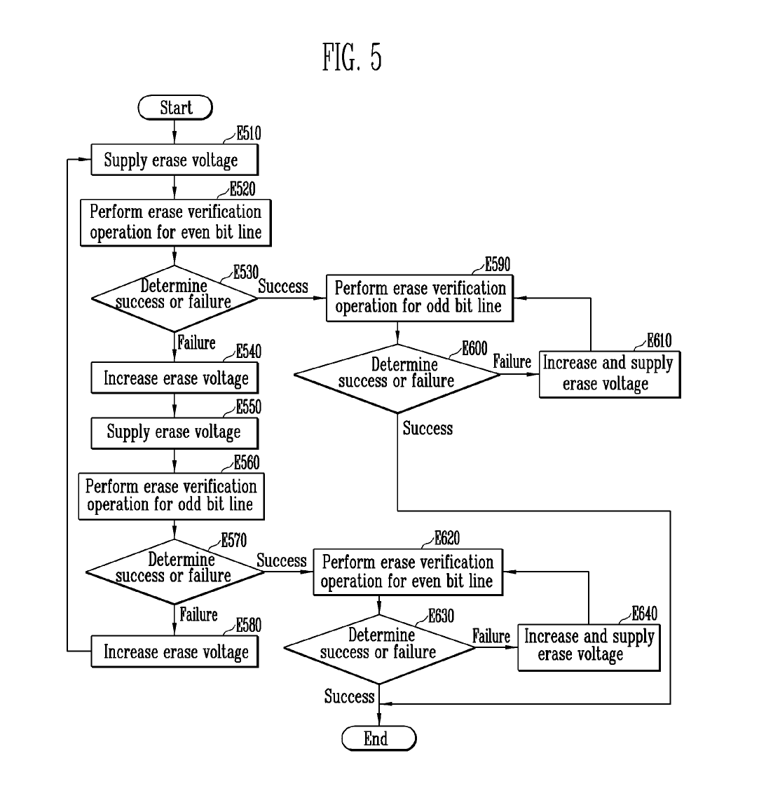

FIG. 3 is a flowchart illustrating a method of erasing the nonvolatile memory device according to an embodiment of this disclosure, and FIG. 4 is a waveform showing an erase voltage and a verification voltage for illustrating a method of erasing the nonvolatile memory device according to an embodiment of this disclosure.

The method of erasing a nonvolatile memory device according to an embodiment of present invention related to FIGS. 2 to 4 is described below.

(1) Supply erase voltage at step E310

The voltage generator 150 generates the erase voltage Vera in response to the control signal of the controller 160. The generated erase voltage Vera is provided to the P well of the semiconductor substrate having the memory cell block 110 disposed therein. For example, the verification voltage Vver of about 0 V and the erase voltage Vera of about 15 V to about 25 V may be outputted. The erase voltage Vera is provided to the P well of the semiconductor substrate, so that the data stored in the memory cells of the memory cell block 110 are erased. That is, the distribution of threshold voltages of the memory cells shifts to 0 V or lower.

(2) Perform erase verification operation for even bit lines at step E320

The erase verification operation is performed for memory cells coupled to the even bit lines coupled to the memory cell block 110. FIGS. 3-4 shows that the even bit lines were chosen at step E320 and odd bit lines were chosen at the step E350 to perform the verification operation; however, it should be readily understood that the process according to an embodiment of the present invention is not limited in that order. This also applies to an embodiment of the present invention related to FIGS. 2 and 5, which is described below. The erase verification operation is performed by supplying the verification voltage Vver, supplied from the voltage generator 150, to relevant word lines of the memory cell block 110 through the X decoder 140 and detecting voltage levels of the even bit lines using the page buffer unit 120.

(3) Determine success or failure at step E330

The verification unit 130 makes determination based on the verification data from the page buffer unit 120 and generates the success or failure signal based on the determined verification data. For example, if all the memory cells coupled to one even bit line have threshold voltages lower than the verification voltage Vver, it would be determined to be successful. If one or more of a plurality of memory cells have threshold voltages higher than the verification voltage Vver, it would be determined to be a failure.

(4) In the event of a failure determined at step E330, increase the erase voltage at step E340

If a failure is determined at step E330, the erase voltage Vera is increased by a step voltage ΔV, and the process returns to step E310 to repeat the subsequent processes, which are described above, until a success is determined at step E330.

(5) In the event of a success determined at step E330, perform erase verification operation for odd bit lines at step E350

If a success is determined at step E330, the erase verification operation is performed for the memory cells coupled to the odd bit lines coupled to the memory cell block 110. The erase verification operation is performed by supplying the verification voltage Vver, supplied from the voltage generator 150, to the relevant word lines of the memory cell block 110 through the X decoder 140 and detecting voltage levels of the odd bit lines using the page buffer unit 120.

(6) Determine success or failure at step E360

The verification unit 130 makes a determination based on the verification data from the page buffer unit 120 and generates the success or failure signal based on the determined verification data. For example, if all the memory cells coupled to one odd bit line have threshold voltages lower than the verification voltage Vver, it would be determined to be successful. If one or more of a plurality of memory cells have threshold voltages higher than the verification voltage Vver, it would be determined to be a failure. If, however, a success is determined at step E360, the erase operation is finished.

(7) In the event of a failure determined at step

E360, increase erase the voltage at step E370

If a failure is determined at step E360, the erase voltage Vera is increased by the step voltage ΔV and the process returns to steps E380 to E350 to E360 as described above, until a success is determined at step E360.

(8) Supply increased erase voltage at step E380

After step E370, the increased erase voltage

Vera is supplied to the P well of the semiconductor substrate having the memory cell block 110 disposed therein, and the process returns to step E350.

FIG. 5 is a flowchart illustrating another method of erasing the nonvolatile memory device according an embodiment of this disclosure.

The method of erasing the nonvolatile memory device according to an embodiment of this disclosure related to FIGS. 2 and 5 is described below.

(1) Supply erase voltage at step E510

The voltage generator 150 generates the erase voltage Vera in response to the control signal of the controller 160. The generated erase voltage Vera is provided to the P well of the semiconductor substrate having the memory cell block 110 disposed therein. For example, the verification voltage Vver of about 0 V and the erase voltage Vera of about 15 V to about 25 V may be ouputted. The erase voltage Vera is provided to the P well of the semiconductor substrate, so that the data stored in the memory cells of the memory cell block 110 are erased. That is, the distribution of threshold voltages of the memory cells shifts to 0 V or lower.

(2) Perform erase verification operation for even bit lines at step E520

After step E510, the erase verification operation is performed for memory cells coupled to the even bit lines coupled to the memory cell block 110. The erase verification operation is performed by supplying the verification voltage Vver, supplied from the voltage generator 150, to relevant word lines of the memory cell block 110 through the X decoder 140 and detecting voltage levels of the even bit lines using the page buffer unit 120.

(3) Determine success or failure at step E530

After step E520, the verification unit 130 makes determination on the verification data from the page buffer unit 120 and generates the success or failure signal based on the determined verification data. For example, if all the memory cells coupled to one even bit line have threshold voltages lower than the verification voltage Vver, it would be determined to be successful. If one or more of a plurality of memory cells have threshold voltages higher than the verification voltage Vver, it would be determined to be a failure. When a success is determined at step E530, the process proceeds to step E590. When a failure is determined at step E530, the process proceeds to step E540.

(4) In the event of a failure determined at step E530, increase the erase voltage at step E540

If a failure is determined at step E530, the erase voltage Vera is increased by a step voltage ΔV and the process proceeds to step E550.

(5) Supply erase voltage at step E550

The increased erase voltage Vera (increased by a step voltage ΔV) is provided to the P well of the semiconductor substrate and the process proceeds to step E560.

(6) Perform an erase verification operation for the odd bit lines at step E560

After step E550, the erase verification operation is performed for the memory cells coupled to the odd bit coupled to the memory cell block 110. The erase verification operation is performed by supplying the verification voltage Vver, supplied from the voltage generator 150, to relevant word lines of the memory cell block 110 through the X decoder 140 and detecting voltage levels of the odd bit lines using the page buffer unit 120. Then, the process proceeds to step E580.

(7) Determine success or failure at step E570

After step E560, the verification unit 130 makes determination on the verification data from the page buffer unit 120 and generates the success or failure signal based on the determined verification data. For example, if all the memory cells coupled to one odd bit line have threshold voltages lower than the verification voltage Vver, it would be determined to be successful. If one or more of a plurality of memory cells have threshold voltages higher than the verification voltage Vver, it would be determined to be a failure. When a success is determined at step E570, the process proceeds to step E620, and when a failure is determined at step E570, the process proceeds to E580 to repeat the subsequent process of E510-E570 until a success is determined at step E530 or E570.

(8) In the event of a failure determined at step E570, supply the increased erase voltage at step E580

If failure is determined at step E570, the erase voltage Vera is increased by the step voltage ΔV, and the process returns to step E510.

(9) In the event of a success determined at step E530, perform an erase verification operation for the odd bit lines at step E590

If a success is determined at step E530, the erase verification operation is performed for the memory cells coupled to the odd bit lines coupled to the memory cell block 110. The erase verification operation is performed by supplying the verification voltage Vver, supplied from the voltage generator 150, to the relevant word lines of the memory cell block 110 through the X decoder 140 and detecting voltage levels of the even bit lines using the page buffer unit 120. The process then proceeds to step E600.

(10) Determine success or failure at step E600

After step E590, the verification unit 130 makes a determination based on the verification data from the page buffer unit 120 and generates the success or failure signal based on the determined verification data. For example, if all the memory cells coupled to one odd bit line have threshold voltages lower than the verification voltage Vver, it would be determined to be successful. If one or more of a plurality of memory cells have threshold voltages higher than the verification voltage Vver, it would be determined to be a failure. If a failure is determined at step E600, the process repeats steps E590 to E600, until a success is determined at step E600. If, however, a success is determined at step E600, the erase operation is finished.

(11) In the event of a failure determined at step E600, increase the erase voltage and provide the increased erase voltage at step E610

If a failure is determined at step E600, the erase voltage Vera is increased by the step voltage ΔV and then the increased erase voltage Vera is provided to the P well of the semiconductor substrate. Next, the process returns to step E590 as described above and then proceeds to step E600, which is also described above.

(12) In the event of a success determined at step E570, perform erase verification operation for the even bit lines at step E620

If a success is determined at step E570, the erase verification operation is performed for the memory cells coupled to the even bit lines coupled to the memory cell block 110. The erase verification operation is performed by supplying the verification voltage Vver, supplied from the voltage generator 150, to the relevant word lines of the memory cell block 110 through the X decoder 140 and detecting voltage levels of the even bit lines using the page buffer unit 120. The process then proceeds to step E630.

(13) Determine success or failure at step E630

After step E620, the verification unit 130 makes a determination based on the verification data from the page buffer unit 120 and generates the success or failure signal based on the determined verification data. For example, if all the memory cells coupled to one even bit line have threshold voltages lower than the verification voltage Vver, it would be determined to be a success. If one or more of a plurality of memory cells have threshold voltages higher than the verification voltage Vver, it would be determined to be a failure. If a failure is determined at step E630, the process is repeated at steps E640 to E620 to E630, until a success is determined at step E630. If, however, a success is determined at step E630, the erase operation is finished.

(14) In the event of a failure determined at step E630, increase the erase voltage and provide the increased erase voltage at step E640

If a failure is determined at step E630, the erase voltage Vera is increased by the step voltage ΔV and then the increased erased voltage Vera by a step of ΔV is provided to the P well of the semiconductor substrate. Next, the process returns to step E620 and then proceeds to step E630, which are described above.

According to various embodiments of this disclosure, after an erase voltage is supplied to the P well of the memory cell block, an erase verification operation is performed for memory cells coupled to even bit lines. If, a result of the erase verification operation, success is determined, an erase verification operation is performed for memory cells coupled to odd bit lines. If, a result of the erase verification operation, failure is determined, the erase voltage is increased and supplied. Next, an erase verification operation is performed for the memory cells coupled to the even bit lines again. Accordingly, the speed of the erase operation can be improved.

What is claimed is:

1. A method of erasing a nonvolatile memory device, the method comprising the steps of:
supplying an erase voltage to a P well of a semiconductor substrate having a memory cell block disposed therein;
performing a first erase verification operation for verifying an erase state of memory cells coupled to even bit lines of the memory cell block;
making a determination of success or failure for the first erase verification operation; and
if, as a result of the determination for the first erase verification operation, all the memory cells coupled to the even bit lines are determined to be erased, performing a second erase verification operation for verifying an erase state of memory cells coupled to odd bit lines of the memory cell block.

2. The method of claim 1, further comprising the steps of:
if, as a result of the determination for the first erase verification operation, one or more of all the memory cells coupled to the even bit lines are determined not to be erased, raising the erase voltage by a step voltage; and
performing the steps from the step of supplying the erase voltage to the P well by using the raised erase voltage.

3. The method of claim 1, further comprising the steps of:
if, as a result of the determination for the first erase verification operation, one or more of all the memory cells coupled to the odd bit lines are determined not to be erased, raising the erase voltage by a step voltage and supplying the raised erase voltage to the P well; and
performing the steps from the step of performing the second erase verification operation.

4. A method of erasing a nonvolatile memory device, the method comprising the steps of:
supplying an erase voltage to a P well of a semiconductor substrate having a memory cell block disposed therein;
performing an even verification operation for verifying an erase state of memory cells coupled to even bit lines of the memory cell block;
if a result of the even verification operation is determined to be failure, raising the erase voltage by a step voltage and performing the steps from the step of supplying the erase voltage to the P well by using the raised erase voltage;
if the result of the even verification operation is determined to be success, performing an odd verification operation for verifying an erase state of memory cells coupled to odd bit lines of the memory cell block;
if a result of the odd verification operation is determined to be failure, raising the erase voltage by the step voltage, supplying the raised erase voltage to the P well, and performing the odd verification operation again; and
if the result of the odd verification operation is determined to be success, finishing an erase operation.

5. The method of claim 4, wherein if, as a result of the even verification operation, at least one of the memory cells coupled to the even bit lines is determined not to be erased, the failure is determined.

6. The method of claim 4, wherein if, as the result of the odd verification operation, at least one of the memory cells coupled to the odd bit lines is determined not to be erased, the failure is determined.

7. A method of erasing a nonvolatile memory device, the method comprising the steps of:
supplying an erase voltage to a P well of a semiconductor substrate having a memory cell block disposed therein;
performing a first erase verification operation for verifying an erase state of memory cells coupled to even bit lines of the memory cell block;
making a determination of success or failure for the first erase verification operation;
if, as a result of the determination, the first erase verification operation is determined to be the failure, raising the erase voltage by a step voltage and supplying the raised erase voltage to the P well;
performing a second erase verification operation for verifying an erase state of memory cells coupled to odd bit lines of the memory cell block;
making a determination of success or failure for the second erase verification operation; and
if, as a result of the determination, the second erase verification operation is determined to be the failure, raising the erase voltage by the step voltage, supplying the raised erase voltage to the P well, and performing the steps from the step of performing the first erase verification operation.

8. The method of claim 7, further comprising the steps of:
if, as a result of the determination, the first erase verification operation is determined to be the success, performing a third erase verification operation for verifying an erase state of the memory cells coupled to the odd bit lines; and
if a result of the third erase verification operation is determined to be success, an erase operation is finished, and if the result of the third erase verification operation is determined to be failure, raising the erase voltage by the step voltage, supplying the raised erase voltage to the P well, and performing the steps from the step of performing the third erase verification operation.

9. The method of claim 7, further comprising the steps of:
if, as a result of the determination, the second erase verification operation is determined to be the success, performing a fourth erase verification operation for verifying an erase state of the memory cells coupled to the even bit lines; and
if a result of the fourth erase verification operation is determined to be success, an erase operation is finished, and if the result of the fourth erase verification operation is determined to be failure, raising the erase voltage by the step voltage, supplying the raised erase voltage to the P well, and performing the steps from the step of performing the fourth erase verification operation.

10. A nonvolatile memory device, comprising:
a memory cell block configured to comprise a plurality of bit lines having a plurality of memory cells coupled thereto;
a circuit group configured to erase the memory cell block; and
a controller configured to control the circuit group,
wherein the controller controls the circuit group so that the circuit group performs processes of;
supplying an erase voltage to a P well of a semiconductor substrate having the memory cell block disposed therein,
performing a first erase verification operation for verifying an erase state of memory cells, coupled to even bit lines of the plurality of bit lines, by supplying a verification voltage to relevant word lines of the memory cell block,
if a result of the first erase verification operation is determined to be failure, raising the erase voltage by a step voltage and supplying the raised erase voltage to the P well,
performing a second erase verification operation for verifying an erase state of memory cells, coupled to odd bit lines of the plurality of bit lines, and
if a result of the second erase verification operation is determined to be failure, raising the erase voltage by the step voltage, supplying the raised erase voltage to the P well, and performing the processes from the process of performing the first erase verification operation.

11. The nonvolatile memory device of claim 10, wherein the circuit group comprises:
a page buffer unit coupled to the plurality of bit lines and configured to detect verification data for the plurality of memory cells;
a verification unit configured to determine an erase operation for the plurality of memory cells, coupled to the plurality of bit lines, based on the verification data; and
a voltage generator configured to supply the verification voltage to the relevant word lines and supply the erase voltage to the P well.

12. A nonvolatile memory device, comprising:
a memory cell block configured to comprise a plurality of even and odd bit lines having a plurality of memory cells coupled thereto;
a page buffer unit coupled to the plurality of even and odd bit lines and configured to detect verification data of the plurality of memory cells; and
a voltage generator configured to supply a verification voltage to word lines of the memory cell block and supply an erase voltage to a P well of a semiconductor substrate having the memory cell block disposed therein,
wherein after the voltage generator supplies the erase voltage to the P well,
the page buffer unit performs an erase verification operation for memory cells coupled to the even bit lines, from among the plurality of memory cells, and if a result of the erase verification operation is determined to be success, performs the erase verification operation for memory cells coupled to the odd bit lines, from among the plurality of memory cells.

13. The nonvolatile memory device of claim 12, wherein if a result of the erase verification operation for the memory cells coupled to the even bit lines is determined to be failure,
the voltage generator raises the erase voltage by the step voltage and supplies the raised erase voltage to the P well, and
the page buffer unit performs the erase verification operation for the memory cells coupled to the even bit lines again.

14. The nonvolatile memory device of claim 12, wherein if a result of the erase verification operation for the memory cells coupled to the odd bit lines is determined to be failure,
the voltage generator raises the erase voltage by the step voltage and supplies the raised erase voltage to the P well, and
the page buffer unit performs the erase verification operation for the memory cells coupled to the odd bit lines again.
